(19) United States
(12) Patent Application Publication
(10) Pub. No.: US 2005/0120286 A1
(43) Pub. Date: Jun. 2, 2005

(54) Method and apparatus for data reproducing using iterative decoding in a disk drive

(75) Inventor: Manabu Akamatsu, Ome-shi (JP)

Correspondence Address: PILLSBURY WINTHROP, LLP, P.O. BOX 10500, MCLEAN, VA, 22102, US

(73) Assignee: KABUSHIKI KAISHA TOSHIBA, Tokyo (JP)

(21) Appl. No.: 10/995,070

(22) Filed: Nov. 23, 2004

(30) Foreign Application Priority Data
Nov. 28, 2003 (JP) 2003-399814

(51) Int. Cl. H03M 13/03

(52) U.S. Cl. 714/792

(57) ABSTRACT

A disk drive using a read/write channel including an iteration decoder for performing iterative decoding processing is disclosed. The iteration decoder has an RLL error detector for detecting a burst error portion from an LLR group output from the channel decoder, and an LLR adjuster. The LLR adjuster makes adjustment by reducing the value of the LLR group corresponding to the detected burst error portion.

### CROSS-REFERENCE TO RELATED APPLICATIONS

This application is based upon and claims the benefit of priority from prior Japanese Patent Application No. 2003-399814, filed Nov. 28, 2003, the entire contents of which are incorporated herein by reference.

### BACKGROUND OF THE INVENTION

1. Field of the Invention

The present invention relates, in general, to the field of disk drives and in particular, to a data reproducing apparatus to which an iterative decoding method is applied.

2. Description of the Related Art

In general, in the field of disk drives typified by hard disk drives, a signal processing circuit called a read channel is used which processes a data signal read from a disk medium (hereinafter, simply referred to as a disk) by a head to reproduce original data.

Usually, the signal processing circuit is constructed of a specifically designed LSI. The signal processing circuit includes a write channel for processing write data to record data on a disk. The signal processing circuit is called also a read/write channel or a data channel.

A present read/write channel adopts a data decoding mode (data reproducing method) which is a combination of a partial response mode and a viterbi decoding method, the so-called partial response maximum likelihood (PRML) mode.

In recent years, to achieve a further higher recording density, in addition to the PRML mode, various signal processing modes for improving the rate of error correction especially have been proposed. Among these modes, a low-density parity check (LDPC) encoding/iterative decoding mode has received widespread attention (for example, see “Coding and Iterative Detection for Magnetic Recording Channels” by Zining Wu, Kluwer Academic Publishers). Further, in addition to this, other various iterative decoding modes have been proposed (for example, see Jpn. Pat. Appln. KOKAI Publication No. 2003-68024).

As for the above-described iterative decoding method, when the method is applied to the data reproducing system of a disk drive, a thermal asperity phenomenon caused by a giant magnetoresistive (GMR) device has been recognized, and when a read data signal includes burst noise because of the dropout of the read data signal, a phenomenon in which errors diffuse has been recognized. For this reason, for example, this method presents a problem that an error correction function to which, for example, a Reed-Solomon decoding method is applied will be degraded.

### BRIEF SUMMARY OF THE INVENTION

In accordance with one embodiment of the present invention, there is provided a disk drive which can improve a decoding function for a burst error and secure a sufficient error correction function in a data reproducing operation by an iterative decoding method.

The disk drive comprises a head which reads a data signal from a disk medium and a data reproducing unit which decodes an encoded data signal read from the disk medium by the head and reproduces data recorded on the disk medium, and the data reproducing unit includes: an iterative decoding unit for performing an iterative decoding processing including a posteriori probability decoding processing for the encoded data signal; a detecting unit which detects an error portion corresponding to an error included in the encoded data signal from log-likelihood ratio information generated by the iterative decoding processing; and a adjusting unit which adjusts the log-likelihood ratio information corresponding to the error portion detected by the detecting unit to a specified range.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram to show the main portion of a read/write channel related to the first embodiment of the invention.

FIG. 2 is a block diagram to show the main portion of a disk drive related to the present embodiment.

FIG. 3 is a bock diagram to show the concept of a digital magnetic recording system related to the present embodiment.

FIG. 4 is a block diagram to show the main portion of an iteration decoder related to the present embodiment.

FIG. 5 is a graph to show the output group of a channel decoder related to the present embodiment.

FIG. 6 is a graph to show the output signal of an RLL error detector related to the present embodiment.

FIG. 7 is a graph to show the output group of an LLR adjuster related to the present embodiment.

FIG. 8 is a block diagram to show the main portion of a read/write channel related to the second embodiment of the invention.

FIG. 9 is a block diagram to show the main portion of an iteration decoder related to the second embodiment.

FIG. 10 is a block diagram to show the main portion of a read/write channel related to the third embodiment of the invention.

FIG. 11 is a block diagram to show the main portion of an iteration decoder related to the third embodiment.

### DETAILED DESCRIPTION OF THE INVENTION

### (FIRST EMBODIMENT)

The first embodiment of the present invention will be described below with reference to the drawings.

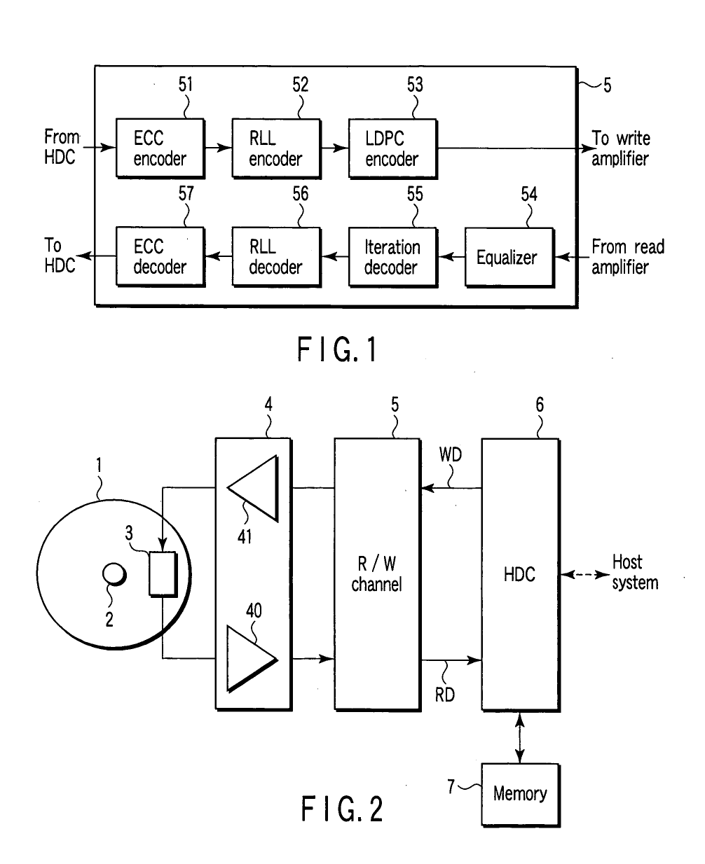

FIG. 1 is a block diagram to show the main portion of a read/write channel 5 which is a data reproducing apparatus related to the present embodiment. FIG. 2 is a block diagram to show the main portion of a disk drive including the read/write channel 5.

(Construction of Disk Drive)

The disk drive, as shown in FIG. 2, has a disk 1 of a recording medium, a head 3, a pre-amplification circuit 4, a read/write (R/W) channel 5, a disk controller (HDC) 6 and a buffer memory 7.

The disk 1 is rotated by a spindle motor (SPM) 2. The head 3 includes a read head device (GMR device) and a write head device and reads data from the disk 1 by the read head device. Further, the head 3 writes data on the disk 1 by the write head device.

The pre-amplification circuit 4 has a read amplifier 40 which amplifies a data signal (read data signal) read by the read head device and sends the amplified data signal to the read/write channel 5. Further, the pre-amplification circuit 4 has a write amplifier 41 which converts the write data signal output from the read/write channel 5 to a write current and supplies the write current to the write head device.

The HDC 6 includes a host interface for connecting the present drive to a host system and outputs write data WD to and inputs read data (reproduced data) RD from the read/write channel 5. The buffer memory 7 is a memory which is accessed by the HDC 6 and temporarily stores read/write data.

(Read/Write Channel)

The read/write channel 5, as shown in FIG. 1, is broadly divided into a read channel connected to the read amplifier 40 and a write channel connected to the write amplifier 41.

The write channel includes an error correction encoder (hereinafter referred to as ECC encoder) 51 connected to the HDC 6, a run-length limited (RLL) encoder 52, and a low-density parity check (LDPC) encoder 53. The LDPC encoder 53 outputs an encoded data signal to the write amplifier 41.

In contrast, the read channel includes an equalizer 54 connected to the read amplifier 40, an iteration decoder 55, an RLL decoder 56, and an error correction decoder (hereinafter referred to as ECC decoder) 57. The equalizer 54 is a digital equalizer which includes an analog-to-digital (A/D) converter on an input side.

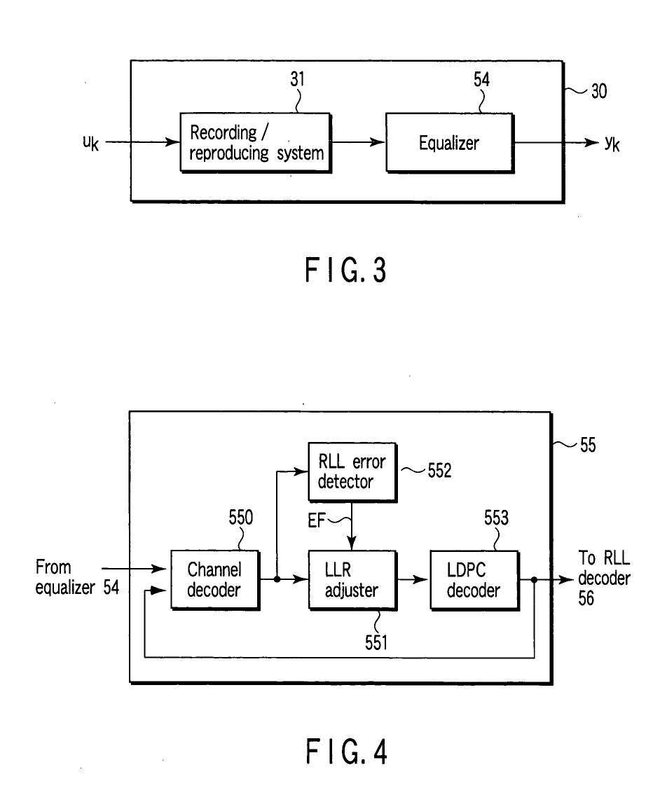

Here, to the disk drive, as shown in FIG. 3, is applied a digital magnetic recording system 30 constructed of the read/write amplifier 4, a digital recording/reproducing system including the head 3 and the disk 1, and the equalizer 54. In this system 30, the characteristic of the equalizer 54 is set in such a way that an output yk for an input Uk has a desired partial response (PR) characteristic. This system 30 constructs a PR channel that is, so to speak, a kind of trellis code.

The read/write channel of the present embodiment regards the PR channel as an inner code and cascades the LDPC encoder 53 in series with the PR channel to realize an iterative decoding processing.

The iteration decoder 55, as shown in FIG. 4, includes a channel decoder 550 connected to the equalizer 54, a log likelihood ratio (LLR) adjuster 551, an RLL code limitation error detector (hereinafter referred to an RLL error detector) 552, and an LDPC decoder 553.

The channel decoder 550 performs the decoding processing of the PR channel (30) of an inner code. The channel decoder 550 performs APP decoding processing for a data signal group output by the equalizer 54 by the use of an a posteriori probability (APP) decoding algorithm, for example, a soft-output viterbi algorithm or the like.

The channel decoder 550 outputs a decoding result and a log likelihood ratio (LLR) group (LLR information). The LLR group represents reliability information to show the reliability of the decoding result. That is, the LLR (L(Uk)) is the logarithm of the ratio between the probability P that an output yk from the equalizer 54 is “uk=0” and the probability P that the output yk is “uk=1”

$$L ( {u}_{k} ) = log \frac{P ( {y}_{k} \vert {u}_{k} = 1 )}{P ( {y}_{k} \vert {u}_{k} = 0 )} \qquad ( 1 )$$

As the absolute value of the LLR shown by equation (1) becomes larger, the decoding result from the channel decoder 550 becomes a more correct value.

The LDPC decoder 553 performs decoding processing of an LDPC encoded group that is an outer code coded by the LDPC encoder. Here, if it is assumed that the LLR adjuster 551, which will be described later, does not perform an adjustment function, the LDPC decoder 553 performs the decoding processing by a predetermined decoding algorithm for the decoding result from the channel decoder 550 by the use of the LLR group output from the channel decoder 550. At this time, the LDPC decoder 553 outputs LLR information that is a new log-likelihood ratio group associated with the decoding processing. The predetermined decoding algorithm is one of the decoding algorithms of the LDPC code group, for example, a sum-product algorithm.

The channel decoder 550 has a new LLR group output from the LDPC decoder 553 and the output (encoded data signal group) from the equalizer 54 input thereto and performs the APP decoding processing again. The iterative decoding processing like this is repeated until an end condition is satisfied.

The end condition is that a predetermined number of iterations are completed or that no error is detected in the decoding processing in the LDPC code group. When this iterative decoding processing is ended, the LLR group and the decoding result output from the LDPC decoder 553 are output to the RLL decoder 56.

(Operation of the Embodiment)

Next, the operation of the iteration decoder 55 including the operations of the LLR adjuster 551 and the RLL error detector 552 will be described.

As described above, the channel decoder 550 performs the APP decoding processing and outputs the decoding result and the log-likelihood ratio group (LLR information). The RLL error detector 552 has the LLR group input thereto and performs hard decision processing in which logical “0” is a threshold. The RLL error detector 552 determines whether or not the hard decision group computed by the hard decision processing violates an RLL encoding rule and outputs an error detection flag EF when the hard decision group violates the RLL encoding rule.

Here, when a minimum run length limitation, a maximum run length limitation, and a maximum transition run limitation are not satisfied or a code word not existing in an encoding table is detected, it is determined that the RLL encoding rule is violated.

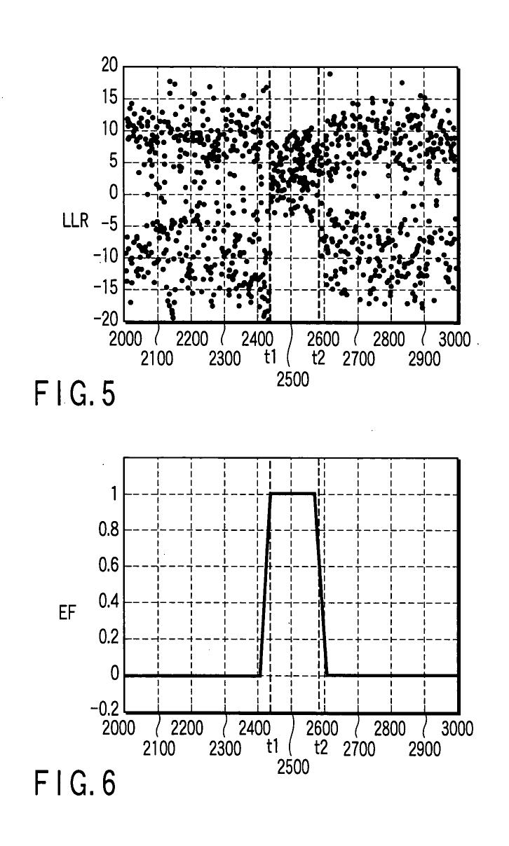

When the decoding result including a burst error causing a reduction in amplitude is output from the channel decoder 550, the LLR group from the channel decoder 550, as shown in FIG. 5, shows such a state from a time t1 to a time t2 that corresponds to a burst error portion. Here, the horizontal axis represents a standardized time axis (t/Tb: Tb shows the bit interval).

When the RLL error detector 552 detects the burst error portion from the LLR group, the RLL error detector 552 outputs an error detection flag EF in response to the detection of the error, as shown in FIG. 6. Here, the error detection flag EF means that a high level portion is the burst error portion.

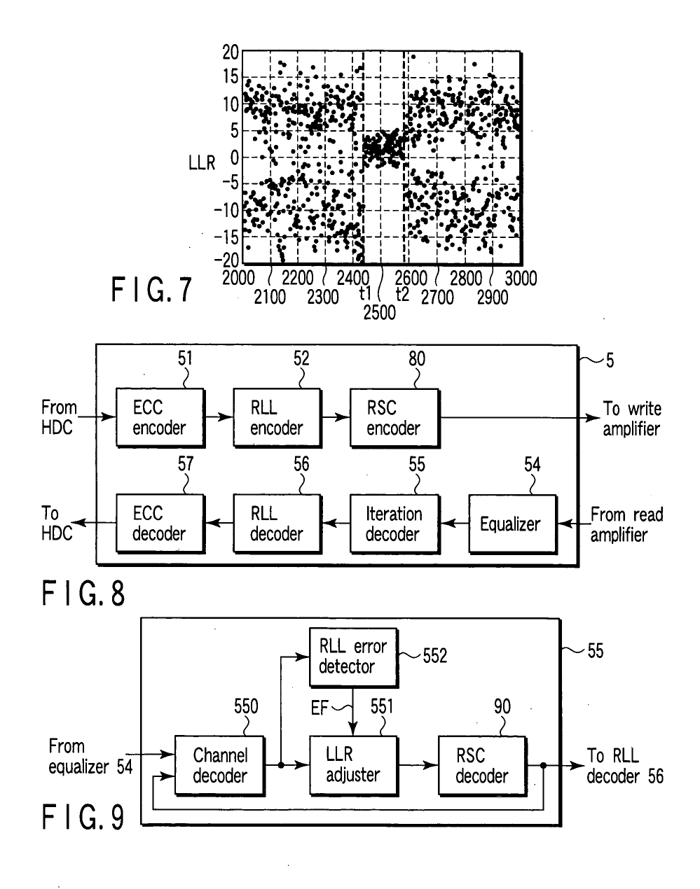

Next, the LLR adjuster 551 adjusts a likelihood value (level) to 1/N for the LLR group input from the channel decoder 550 according to the error flag EF from the RLL error detector 552. To be more specific, the LLR adjuster 551, as shown in FIG. 7, adjusts the value (level) of a portion corresponding to the time t1 to the time t2 of the LLR group (burst error portion), for example, to ½ or ⅓. In this case, the LLR adjuster 551 may make adjustment of subtracting a certain value from the portion of the LLR group corresponding to the time t1 to the time t2.

The LDPC decoder 553 performs decoding processing for the decoding result output from the channel decoder 550 by the use of the LLR group adjusted by the LLR adjuster 551. Then, the LDPC decoder 553 outputs a new LLR group associated with the decoding processing to the channel decoder 550.

When the iterative decoding processing described above is ended, the iteration decoder 55 outputs the LLR group and the decoding result output from the LDPC decoder 553 to the RLL decoder 56.

According to the iteration decoder 55 of the present embodiment, the RLL error detector 552 detects the burst error portion included in the decoding result of the inner code output from the channel decoder 550 from the LLR group (outputs an error detection flag EF). The LLR adjuster 551 limits the value of the LLR group corresponding to the error portion; to be more specific, it reduces likelihood corresponding to the error portion to prevent the effect of reliability determination of the burst error portion.

Hence, when the LDPC decoder 553 performs the decoding processing of the outer code for the decoding result output from the channel decoder 550 by the use of the LLR group, the effect of the reliability determination of the burst error portion is prevented. In other words, in the iterative decoding processing by the iteration decoder 55, the phenomenon that the burst error included in the decoding result by the APP decoding processing from the channel decoder 550 diffuses can be prevented.

In short, according to the present embodiment, it is possible to improve an iterative decoding function for the encoded data signal including a burst error and, as a result, to secure a sufficient error correction function at the time of reproducing the data.

### (SECOND EMBODIMENT)

FIG. 8 and FIG. 9 are block diagrams to show the main portion of the R/W channel 5 and the iteration decoder 55 related to the second embodiment.

That is, the R/W channel 5 of the present embodiment, as shown in FIG. 8, is constructed in such a way that a recursive systematic convolution (RSC) encoder 80 of the outer code is cascaded in series with the PR channel of the inner code. Hence, the iteration decoder 55, as shown in FIG. 9, performs the iterative decoding processing by the channel decoder 550 for performing the decoding processing of the PR channel of the inner code and the RSC decoder 90 for performing the decoding processing of the RSC encoding group of the outer code.

In this regard, the operation in the iteration decoder 55 including the operations of the LLR adjuster 551 and the RLL error detector 552 is the same as in the case of the first embodiment.

### (THIRD EMBODIMENT)

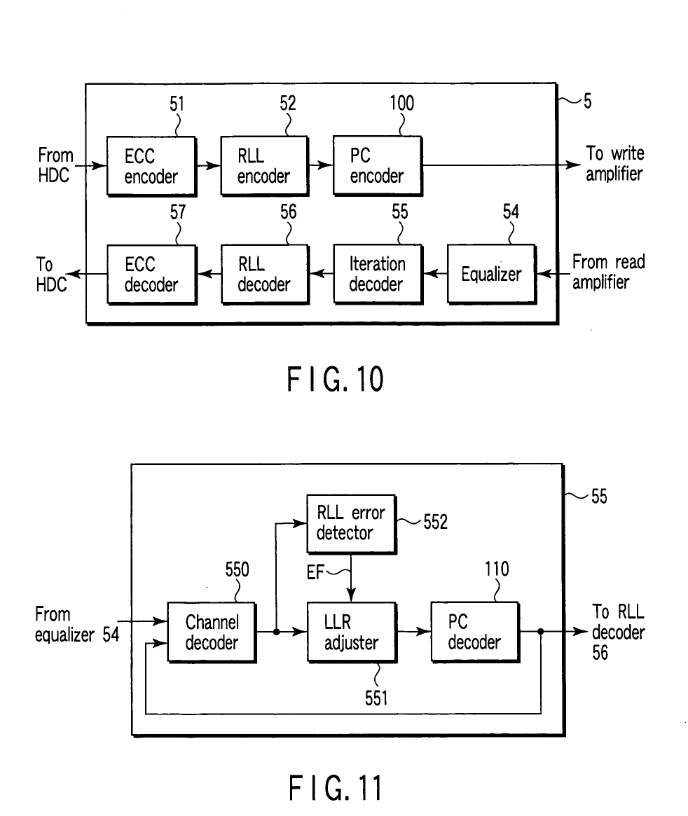

FIG. 10 and FIG. 11 are block diagrams to show the main portion of the R/W channel 5 and the iteration decoder 55 related to the third embodiment.

That is, the R/W channel 5 of the present embodiment, as shown in FIG. 10, is constructed in such a way that a parity check (PC) encoder 100 of the outer code is cascaded in series with the PR channel of the inner code. Hence, the iteration decoder 55, as shown in FIG. 11, performs the iterative decoding processing by the channel decoder 550 for performing the decoding processing of the PR channel of the inner code and the PC decoder 110 for performing the decoding processing of the RSC encoding group of the outer code.

In this regard, the operation in the iteration decoder 55, including the operations of the LLR adjuster 551 and the RLL error detector 552, is the same as in the case of the first embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A disk drive comprising:
a head which reads a data signal recorded on a disk medium; and
a data reproducing unit which decodes an encoded data signal read from the disk medium by the head and reproduces data recorded on the disk medium,
wherein the data reproducing unit includes:
an iterative decoding unit which performs iterative decoding processing including a posteriori probability decoding processing for the encoded data signal;
a detecting unit which detects an error portion corresponding to an error included in the encoded data signal from log-likelihood ratio information produced by the iterative decoding processing; and
an adjusting unit which adjusts the log-likelihood ratio information corresponding to the error portion detected by the detecting unit.

2. The disk drive according to claim 1, wherein the iterative decoding unit includes:
a first decoder which performs the a posteriori probability decoding processing for the encoded data signal and outputs a decoding result including the log-likelihood ratio information; and
a second decoder which performs the a posteriori probability decoding processing for the decoding result from the first decoder by the use of the log-likelihood ratio information adjusted by the adjusting unit and outputs a decoding result including the log-likelihood ratio information as an input of the first decoder, and
performs iterative decoding processing a predetermined number of times by the first and second decoders and then outputs an output of the second decoder as an iterative decoding result.

3. The disk drive according to claim 1, wherein the detecting unit detects a portion of a log-likelihood ratio group which does not agree with an encoding rule of the encoded data signal from the log-likelihood ratio information as the error portion.

4. The disk drive according to claim 1, wherein the detecting unit performs hard decision processing for a log-likelihood ratio group of the log-likelihood ratio information and detects a portion of the log-likelihood ratio group in which a hard decision group obtained by the hard decision processing does not agree with an encoding rule of the encoded data signal as the error portion.

5. The disk drive according to claim 1, wherein the iterative decoding unit includes:
a first decoder which performs the posteriori probability decoding processing for the encoded data signal and outputs a decoding result including the log-likelihood ratio information; and
a second decoder which performs the a posteriori probability decoding processing for the decoding result from the first decoder by the use of the log-likelihood ratio information adjusted by the adjusting unit and outputs a decoding result including the log-likelihood ratio information as an input of the first decoder, the second decoder being constructed of a low-density parity check (LDPC) decoder for a low-density parity check code.

6. The disk drive according to claim 1, wherein the iterative decoding unit includes:
a first decoder which performs the a posteriori probability decoding processing for the encoded data signal and outputs a decoding result including the log-likelihood ratio information; and
a second decoder which performs the a posteriori probability decoding processing for the decoding result from the first decoder by the use of the log-likelihood ratio information adjusted by the adjusting unit and outputs a decoding result including the log-likelihood ratio information as an input of the first decoder, the second decoder being constructed of a recursive systematic convolution (RSC) decoder for a recursive systematic convolution code.

7. The disk drive according to claim 1, wherein the iterative decoding unit includes:
a first decoder which performs the a posteriori probability decoding processing for the encoded data signal and outputs a decoding result including the log-likelihood ratio information; and
a second decoder which performs the a posteriori probability decoding processing for the decoding result from the first decoder by the use of the log-likelihood ratio information adjusted by the adjusting unit and outputs a decoding result including the log-likelihood ratio information as an input of the first decoder, the second decoder being constructed of a parity check (PC) decoder for a parity check code.

8. The disk drive according to claim 1, wherein the adjusting unit reduces the log-likelihood ratio information to 1/N and outputs it.

9. A data reproducing apparatus comprising:
a signal processing unit which has an encoded data signal input thereto and performs digital signal processing;
an iterative decoding unit which performs iterative decoding processing including a posteriori probability decoding processing for the encoded data signal output from the signal processing unit;
a detecting unit which detects an error portion corresponding to an error included in the encoded data signal from log-likelihood ratio information produced by the iterative decoding processing; and
an adjusting unit which adjusts log-likelihood ratio information corresponding to the error portion detected by the detecting unit within a predetermined range.

10. The data reproducing apparatus according to claim 9, wherein the adjusting unit reduces the log-likelihood ratio information to 1/N and outputs it.

11. The data reproducing apparatus according to claim 9, wherein the iterative decoding unit includes:
a first decoder which performs the a posteriori probability decoding processing for the encoded data signal and outputs a decoding result including the log-likelihood ratio information; and
a second decoder which performs the a posteriori probability decoding processing for the decoding result from the first decoder by the use of the log-likelihood ratio information adjusted by the adjusting unit and outputs a decoding result including the log-likelihood ratio information as an input of the first decoder, and
performs iterative decoding processings a predetermined number of times by the first and second decoders and then outputs an output of the second decoder as an iterative decoding result.

12. The data reproducing apparatus according to claim 9, wherein the detecting unit detects such a portion of a log-likelihood ratio group which does not agree with an encoding rule of the encoded data signal from the log-likelihood ratio information as the error portion.

13. The data reproducing apparatus according to claim 9, wherein the detecting unit performs hard decision processing for a log-likelihood ratio group of the log-likelihood ratio information and detects a portion of the log-likelihood ratio group in which a hard decision group obtained by the hard decision processing does not agree with an encoding rule of the encoded data signal as the error portion.

14. The data reproducing apparatus according to claim 9, wherein the iterative decoding unit includes:
a first decoder which performs the a posteriori probability decoding processing for the encoded data signal and outputs a decoding result including the log-likelihood ratio information; and
a second decoder which performs the a posteriori probability decoding processing for the decoding result from the first decoder by the use of the log-likelihood ratio information adjusted by the adjusting unit and outputs a decoding result including the log-likelihood ratio information as an input of the first decoder, the second decoder being constructed of a low-density parity check (LDPC) decoder for a low-density parity check code.

15. The data reproducing apparatus according to claim 9, wherein the iterative decoding unit includes:
a first decoder which performs the a posteriori probability decoding processing for the encoded data signal and outputs a decoding result including the log-likelihood ratio information; and
a second decoder which performs the a posteriori probability decoding processing for the decoding result from the first decoder by the use of the log-likelihood ratio information adjusted by the adjusting unit and outputs a decoding result including the log-likelihood ratio information as an input of the first decoder, the second decoder being constructed of a recursive systematic convolution (RSC) decoder for a recursive systematic convolution code.

16. The data reproducing apparatus according to claim 9, wherein the iterative decoding unit includes:
a first decoder which performs the a posteriori probability decoding processing for the encoded data signal and outputs a decoding result including the log-likelihood ratio information; and
a second decoder which performs the a posteriori probability decoding processing for the decoding result from the first decoder by the use of the log-likelihood ratio information adjusted by the adjusting unit and outputs a decoding result including the log-likelihood ratio information as an input of the first decoder, the second decoder being constructed of a parity check (PC) decoder for a parity check code.

17. A method of reproducing data read from a disk medium in a disk drive, the method comprising:
performing first decoding processing which performs a posteriori probability decoding processing for a decoded data signal read from the disk medium and outputs a first decoding result including log-likelihood ratio information;
detecting an error portion corresponding to an error included in the decoded data signal from the log-likelihood ratio information;
regulating the log-likelihood ratio information corresponding to the detected error portion to 1/N;
performing second decoding processing which performs a posteriori probability decoding processing for the first decoding result by the use of the adjusted log-likelihood ratio information and outputs a second decoding result including the log-likelihood ratio information as an input of processing of the first decoding result; and
performing iterative decoding processing including the first and second decoding processing a predetermined number of times and then outputting an output of the second decoding processing as an iterative decoding result.
